(19) United States
(12) Patent Application Publication
(10) Pub. No.: US 2021/0363379 A1
(43) Pub. Date: Nov. 25, 2021

(54) EPOXY RESIN COMPOSITION FOR SEMICONDUCTOR DEVICE ENCAPSULATING FILM, SEMICONDUCTOR DEVICE ENCAPSULATING FILM AND SEMICONDUCTOR DEVICE ENCAPSULATED USING THE SAME

(71) Applicant: SAMSUNG SDI CO., LTD., Yongin-si (KR)

(72) Inventors: Seung Woo HONG, Suwon-si (KR); Jin Min CHEON, Suwon-si (KR); Young Joon LEE, Suwon-si (KR)

(21) Appl. No.: 17/318,047

(22) Filed: May 12, 2021

(30) Foreign Application Priority Data
May 19, 2020 (KR) 10-2020-0060028

(51) Int. Cl. C09D 163/00

(52) U.S. Cl. CPC C09D 163/00

(57) ABSTRACT

An epoxy resin composition for semiconductor device encapsulation films, a film for encapsulation of semiconductor devices, and a semiconductor device encapsulated using the same, the epoxy resin composition including a liquid epoxy resin; a curing agent; about 2 wt % to about 10 wt % of a binder resin; and about 50 wt % or more of an oxide, a nitride, a carbide, or a hydroxide of gadolinium, boron, samarium, cadmium, or europium, all wt % being based on a total weight of the epoxy resin composition.

### CROSS-REFERENCE TO RELATED APPLICATION

Korean Patent Application No. 10-2020-0060028, filed on May 19, 2020 in the Korean Intellectual Property Office, and entitled: “Epoxy Resin Composition for Semiconductor Device Encapsulating Film, Semiconductor Device Encapsulating Film and Semiconductor Device Encapsulated Using the Same,” is incorporated by reference herein in its entirety.

### BACKGROUND

### 1. Field

Embodiments relates to an epoxy resin composition for semiconductor device encapsulation films, a film for encapsulation of semiconductor devices, and a semiconductor device encapsulated using the same.

### 2. Description of the Related Art

Cosmic rays generally refer to all sorts of highly energetic particles and radiation that hit the earth from outer space, and may be generated from explosions of supernovae in the galaxy.

Primary cosmic rays entering the earth's atmosphere may collide with nitrogen or oxygen atoms, producing secondary cosmic rays, which may affect humans and electronic products in daily life. Besides protons present in a negligible amount (0.5% or less) and elementary particles having little interaction with substances colliding therewith, secondary cosmic rays may consist of neutrons. Cosmic-ray neutrons may contribute about 95% or more of soft errors caused by secondary cosmic rays.

Due to small sizes thereof, neutrons may penetrate most materials, including the human body and, in rare cases, may collide with atomic nuclei. The amount of neutron radiation (radiation per unit time) varies depending on altitude, and the number of neutrons at aircraft cruising altitudes (10 km to 15 km above the ground) is about 300 times that at ground level.

### SUMMARY

The embodiments may be realized by providing an epoxy resin composition for semiconductor device encapsulation films, the epoxy resin composition including a liquid epoxy resin; a curing agent; about 2 wt % to about 10 wt % of a binder resin; and about 50 wt % or more of an oxide, a nitride, a carbide, or a hydroxide of gadolinium, boron, samarium, cadmium, or europium, all wt % being based on a total weight of the epoxy resin composition.

The liquid epoxy resin may include a bisphenol A epoxy resin, a hydrogenated bisphenol A epoxy resin, or a combination thereof.

The binder resin may include an epoxy-modified (meth)acrylic copolymer.

The oxide, nitride, carbide, or hydroxide of gadolinium, boron, samarium, cadmium, or europium may have an average particle diameter (D₅₀) of about 0.1 μm to about 50 μm.

The oxide, nitride, carbide, or hydroxide of gadolinium, boron, samarium, cadmium, or europium may be present in an amount of about 50 wt % to about 90 wt %, based on the total weight of the epoxy resin composition.

The epoxy resin composition may include at least two of an oxide, a nitride, a carbide, or a hydroxide of gadolinium, boron, samarium, cadmium, or europium.

One oxide, nitride, carbide, or hydroxide of gadolinium, boron, samarium, cadmium, or europium of the at least two oxides, nitrides, carbides, or hydroxides of gadolinium, boron, samarium, cadmium, or europium may have an average particle diameter (D₅₀) that is different from that of the other oxide, nitride, carbide, or hydroxide of gadolinium, boron, samarium, cadmium, or europium of the at least two oxides, nitrides, carbides, or hydroxides of gadolinium, boron, samarium, cadmium, or europium.

The epoxy resin composition may include about 0.5 wt % to about 25 wt % of the liquid epoxy resin; about 0.1 wt % to about 15 wt % of the curing agent; about 2 wt % to about 10 wt % of the binder resin; and about 50 wt % to about 90 wt % of the oxide, nitride, carbide, or hydroxide of gadolinium, boron, samarium, cadmium, or europium, all wt % being based on a total weight of the epoxy resin composition.

The embodiments may be realized by providing a film for encapsulation of semiconductor devices, the film including a base film or a release film; and an epoxy resin composition coated on the base film or the release film, the epoxy resin composition being in a semi-cured state, wherein the epoxy resin composition includes the epoxy resin composition for semiconductor device encapsulation films according to an embodiment.

The liquid epoxy resin may include a bisphenol A epoxy resin, a hydrogenated bisphenol A epoxy resin, or a combination thereof.

The binder resin may include an epoxy-modified (meth)acrylic copolymer.

The oxide, nitride, carbide, or hydroxide of gadolinium, boron, samarium, cadmium, or europium may have an average particle diameter (D₅₀) of about 0.1 μm to about 50 μm.

The oxide, nitride, carbide, or hydroxide of gadolinium, boron, samarium, cadmium, or europium may be present in an amount of about 50 wt % to about 90 wt %, based on the total weight of the epoxy resin composition.

The epoxy resin composition may include at least two of an oxide, a nitride, a carbide, or a hydroxide of gadolinium, boron, samarium, cadmium, or europium.

One oxide, nitride, carbide, or hydroxide of gadolinium, boron, samarium, cadmium, or europium of the at least two oxides, nitrides, carbides, or hydroxides of gadolinium, boron, samarium, cadmium, or europium may have an average particle diameter (D₅₀) that is different from that of the other oxide, nitride, carbide, or hydroxide of gadolinium, boron, samarium, cadmium, or europium of the at least two oxides, nitrides, carbides, or hydroxides of gadolinium, boron, samarium, cadmium, or europium.

The epoxy resin composition may include about 0.5 wt % to about 25 wt % of the liquid epoxy resin; about 0.1 wt % to about 15 wt % of the curing agent; about 2 wt % to about 10 wt % of the binder resin; and about 50 wt % to about 90 wt % of the oxide, nitride, carbide, or hydroxide of gadolinium, boron, samarium, cadmium, or europium, all wt % being based on a total weight of the epoxy resin composition.

The embodiments may be realized by providing a semiconductor device encapsulated using the film for encapsulation of semiconductor devices according to an embodiment.

### DETAILED DESCRIPTION

As used herein, the singular forms “a”, “an”, and “the” are intended to include the plural forms as well, unless the context clearly indicates otherwise. As used herein, the term “or” is not an exclusive term, e.g., “A or B” would include A, B, or A and B.

It will be further understood that the terms “comprises,” “comprising,” “includes,” and “including,” when used in this specification, specify the presence of stated features, integers, steps, operations, elements, components, and/or groups thereof, but do not preclude the presence or addition of one or more other features, integers, steps, operations, elements, components, and/or groups thereof.

Further, a numerical value related to a certain component is construed to include a tolerance range in interpretation of components, unless clearly stated otherwise.

As used herein to represent a specific numerical range, the expression “a to b” means “≥a and ≤b”.

As used herein, “average particle diameter (D₅₀)” is a typical particle diameter measure and refers to a particle diameter corresponding to 50% by volume in a volume cumulative distribution of particles.

An epoxy resin composition for semiconductor device encapsulation films according to one embodiment may include, e.g., a liquid epoxy resin; a curing agent; about 2 wt % to about 10 wt % of a binder resin; and about 50 wt % or more of an oxide, a nitride, a carbide, or a hydroxide of gadolinium, boron, samarium, cadmium, or europium. The wt % is based on a total weight of the composition.

Now, each component of the epoxy resin composition for semiconductor device encapsulation films (hereinafter referred to as an “epoxy resin composition”) will be described in more detail.

Liquid Epoxy Resin

The liquid epoxy resin may help impart better adhesion to a film formed therefrom than a solid epoxy resin.

The liquid epoxy resin may include a suitable liquid epoxy resin for encapsulation of semiconductor devices. In an implementation, the liquid epoxy resin may include an epoxy compound containing at least two epoxy groups per molecule. Examples of the liquid epoxy resin may include bisphenol A epoxy resins, bisphenol F epoxy resins, bisphenol AD epoxy resins, bisphenol S epoxy resins, fluorine epoxy resins, naphthalene epoxy resins, biphenyl epoxy resins, glycidyl amine epoxy resins, alicyclic epoxy resins (e.g., a hydrogenated bisphenol A epoxy resin), dicyclopentadiene epoxy resins, polyether epoxy resins, silicone-modified epoxy resins, and the like. These may be used alone or in combination thereof. In an implementation, the liquid epoxy resin may include a bisphenol A epoxy resin or a hydrogenated bisphenol A epoxy resin. In an implementation, the epoxy resin composition can have further improved neutron shielding properties due to neutron scattering effects due to high hydrogen contents of these epoxy resins.

The epoxy resin may have an epoxy equivalent of about 100 g/eq to about 500 g/eq, in consideration of curability of the epoxy resin composition. Within this range, the degree of cure of the epoxy resin composition can be increased.

In an implementation, the liquid epoxy resin may be present in an amount of about 0.5 wt % to about 25 wt %, based on the total weight of the epoxy resin composition. Within this range, reduction in curability of the composition may be prevented. In an implementation, the epoxy resin may be present in an amount of about 3 wt % to 15 wt % in the epoxy resin composition.

Curing Agent

The curing agent may include a suitable curing agent for encapsulation of semiconductor devices. In an implementation, the curing agent may include acid anhydride curing agents, phenolic curing agents, amine curing agents, or imidazole curing agents. Examples of the acid anhydride curing agents may include phthalic anhydrides, hexahydrophthalic anhydrides, alkylhexahydrophthalic anhydrides (for example, 4-methylhexahydrophthalic anhydride), alkyltetrahydrophthalic anhydrides, trialkyltetrahydrophthalic anhydrides, succinic anhydrides, methylnadic anhydrides, trimellitic anhydrides, pyromellitic anhydrides, and methylnorbornane-2,3-dicarboxylic acids. Examples of the phenolic curing agents may include polyhydric phenol compounds including phenol aralkyl resins, phenol novolac resins, polyfunctional phenol resins, Xylok phenol resins, cresol novolac phenol resins, naphthol phenol resins, terpene phenol resins, dicyclopentadiene phenol resins, novolac phenol resins synthesized from bisphenol A and resol, tris(hydroxyphenyl)methane, and dihydroxybiphenyl. Examples of the amine curing agents may include melamine, metaphenylenediamine, dimethylaniline, diaminodiphenylmethane, and diaminodiphenylsulfone. Examples of the imidazole curing agents may include 2-methylimidazole, 2-ethyl-4-methylimidazole, 1-cyanoethyl-2-undecylimidazolium trimellitate, and epoxy-imidazole adducts. These compounds may be used alone or in combination thereof. In an implementation, the curing agent may include an amine curing agent or an imidazole curing agent having a high hydrogen content, e.g., melamine, diaminodiphenylmethane, or 2-methylimidazole.

In an implementation, the curing agent may be present in an amount of about 0.1 wt % to about 15 wt %, based on the total weight of the epoxy resin composition. Within this range, reduction in curability of the composition may be prevented. In an implementation, the curing agent may be present in an amount of about 1 wt % to 10 wt % in the epoxy resin composition.

A mixing ratio of the liquid epoxy resin to the curing agent may vary depending on requirements such as mechanical properties in a package and moisture resistance reliability. In an implementation, a chemical equivalent ratio of the liquid epoxy resin to the curing agent may range from about 0.95 to about 3. Within this range, the epoxy resin composition may exhibit good strength after curing. In an implementation, a chemical equivalent ratio of the epoxy resin to the curing agent may range from about 1 to about 2. In an implementation, a chemical equivalent ratio of the epoxy resin to the curing agent may range from about 1 to about 1.75.

Binder Resin

The binder resin may help reduce brittleness of a cured system, thereby increasing fracture toughness of the cured system while relieving internal stress of the cured system.

The binder resin may include a suitable binder resin for encapsulation of semiconductor devices. The binder resin may include, e.g., epoxy-modified urethane copolymers, epoxy-modified (meth)acrylic copolymers, polyester-based polymer resins (for example, polyester polyol), acrylic rubbers dispersed in epoxy resins, core-shell type rubbers, acrylonitrile-butadiene rubber (NBR), carboxy-terminated butadiene nitrile (CTBN) rubber, acrylonitrile-butadiene-styrene, or polymethyl siloxane. These may be used alone or in combination thereof. In an implementation, the binder resin may include an epoxy-modified (meth)acrylic copolymer. In an implementation, the binder resin may provide flexibility to a cured composition layer while providing additional neutron scattering effects due to high hydrogen content thereof.

The binder resin may be present in an amount of about 2 wt % to about 10 wt % (e.g., 2 wt %, 3 wt %, 4 wt %, 5 wt %, 6 wt %, 7 wt %, 8 wt %, 9 wt %, or 10 wt %), based on the total weight of the epoxy resin composition. Within this range, the epoxy resin composition may have good film formability (wettability and leveling properties) while having good heat resistance due to high crosslinking density of cured components. In addition, within this range, the oxide, nitride, carbide, or hydroxide of gadolinium, boron, samarium, cadmium, or europium may be incorporated in sufficient amounts into the composition, whereby the composition may have high neutron shielding capability. The binder resin may be present in an amount of, e.g., about 2 wt % to about 8 wt %, or about 2 wt % to about 6 wt %, in the epoxy resin composition.

Oxide, Nitride, Carbide, or Hydroxide of Gadolinium, Boron, Samarium, Cadmium, or Europium

An oxide, nitride, carbide, or hydroxide of gadolinium, boron, samarium, cadmium, or europium, e.g., gadolinium oxide, gadolinium nitride, gadolinium carbide, gadolinium hydroxide, boron oxide, boron nitride, boron carbide, boron hydroxide, samarium oxide, samarium nitride, samarium carbide, samarium hydroxide, cadmium oxide, cadmium nitride, cadmium carbide, cadmium hydroxide, europium oxide, europium nitride, europium carbide, europium hydroxide, are compounds having a high cross-section for neutron capture. Accordingly, when a semiconductor device is encapsulated with a film for encapsulation of semiconductor devices that contains these compounds, neutron shielding through semiconductor package-level neutron capture may be achieved.

The oxide, nitride, carbide, or hydroxide of gadolinium, boron, samarium, cadmium, or europium may be present in an amount of about 50 wt % or more, based on the total weight of the epoxy resin composition. Maintaining the amount of the oxide, nitride, carbide, or hydroxide of gadolinium, boron, samarium, cadmium, or europium at about 50 wt % or more may help ensure that the composition provides a desired level of neutron shielding.

The oxide, nitride, carbide, or hydroxide of gadolinium, boron, samarium, cadmium, or europium may be present in an amount of, e.g., about 50 wt % to 90 about wt % (e.g., 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, or 90 wt %), about 60 wt % to 88 wt %, or about 80 wt % to about 87 wt %, in the epoxy resin composition. Within this range, the epoxy resin composition may help provide a high level of neutron shielding, may be easily formed into a film, and may help secure flexibility of the film, thereby preventing the film from breaking upon bonding.

The oxide, nitride, carbide, or hydroxide of gadolinium, boron, samarium, cadmium, or europium may have suitable particle shape, e.g., a spherical particle shape, a flake particle shape, or an amorphous particle shape.

The size of the oxide, nitride, carbide, or hydroxide of gadolinium, boron, samarium, cadmium, or europium may vary depending on desired properties. In an implementation, the oxide, nitride, carbide, or hydroxide of gadolinium, boron, samarium, cadmium, or europium may have an average particle diameter (D₅₀) of about 0.1 μm to about 50 μm (e.g., 0.1 μm, 0.2 μm, 0.3 μm, 0.4 μm, 0.5 μm, 0.6 μm, 0.7 μm, 0.8 μm, 0.9 μm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, or 50 μm), about 0.5 μm to about 25 μm, or about 1.0 μm to about 12 μm. Within this range, the epoxy resin composition may avoid a reduction in adhesive strength after bonding (e.g., due to increase in melt viscosity at a predetermined bonding temperature) and may provide a high level of neutron shielding due to high filler loading rate thereof. In addition, the epoxy resin composition may include a combination of at least two compounds of oxides, nitrides, carbides, or hydroxides of gadolinium, boron, samarium, cadmium, or europium, the at least two compounds having different particle diameters (D₅₀). In an implementation, the epoxy resin composition may include a mixture obtained by mixing one of an oxide, nitride, carbide, or hydroxide of gadolinium, boron, samarium, cadmium, or europium, the one compound having an average particle diameter (D₅₀) of about 4 μm to about 15 μm, with another of an oxide, nitride, carbide, or hydroxide of gadolinium, boron, samarium, cadmium, or europium, the other compound having an average particle diameter (D₅₀) of about 0.1 μm to 3 μm. In this case, the epoxy resin composition may have further increased filler loading rate.

In an implementation, the epoxy resin composition may include at least two of an oxide, nitride, carbide, or hydroxide of gadolinium, boron, samarium, cadmium, or europium. These compounds may help absorb neutrons in different energy ranges. Accordingly, when the epoxy resin composition includes at least two of these compounds, the epoxy resin composition may help absorb neutrons over extended energy ranges, thereby exhibiting further improved neutron shielding properties.

The epoxy resin composition may further include a curing accelerator.

Curing Accelerator

As used herein, “curing accelerator” may refer to a substance that promotes reaction between the epoxy resin and the curing agent. Examples of the curing accelerator may include tertiary amines, organometallic compounds, organophosphorus compounds, imidazole compounds, and boron compounds.

Examples of the tertiary amines may include benzyldimethylamine, triethanolamine, triethylenediamine, diethylaminoethanol, tri(dimethylaminomethyl)phenol, 2-2-(dimethylaminomethyl)phenol, 2,4,6-tris(diaminomethyl)phenol, tri-2-ethylhexylate, and the like. Examples of the organometallic compounds may include chromium acetylacetonate, zinc acetylacetonate, nickel acetylacetonate, and the like. Examples of the organophosphorus compounds may include tris-4-methoxyphosphine, tetrabutylphosphonium bromide, tetraphenylphosphonium bromide, phenylphosphine, diphenylphosphine, triphenylphosphine, triphenylphosphine triphenylborane, triphenylphosphine-1,4-benzoquinone adducts, and the like. Examples of the imidazole compounds may include 2-phenyl-4-methylimidazole, 2-methylimidazole, 2-phenylimidazole, 2-aminoimidazole, 2-methyl-1-vinylimidazole, 2-ethyl-4-methylimidazole, 2-heptadecylimidazole, and the like. Examples of the boron compounds may include tetraphenylphosphonium-tetraphenylborate, triphenylphosphine tetraphenylborate, tetraphenylboron salt, trifluoroborane-n-hexylamine, trifluoroborane monoethylamine, tetrafluoroborane triethylamine, tetrafluoroborane amine, and the like. In an implementation, besides these compounds, the curing accelerator may include, e.g., 1,5-diazabicyclo[4.3.0]non-5-ene (DBN), (1,8-diazabicyclo[5.4.0]undec-7-ene (DBU), a phenol novolac resin salt, or the like.

In an implementation, the curing accelerator may be used in the form of an adduct prepared by pre-reacting the curing accelerator with the epoxy resin or the curing agent.

In an implementation, the curing accelerator may be present in an amount of about 0.01 wt % to about 2 wt %, based on the total weight of the epoxy resin composition. Within this range, the curing accelerator may promote curing of the composition while increasing the degree of cure of the composition. In an implementation, the curing accelerator may be present in an amount of about 0.02 wt % to about 1.5 wt % in the epoxy resin composition.

In an implementation, the epoxy resin composition may further include a coupling agent or a release agent.

Coupling Agent

The coupling agent may help increase interfacial strength between the epoxy resin and the inorganic fillers through reaction with the epoxy resin and the inorganic fillers, and may include, e.g., a silane coupling agent. The silane coupling agent may include a suitable silane coupling agent that can increase interfacial strength between the epoxy resin and the inorganic fillers through reaction with the epoxy resin and the inorganic fillers. Examples of the silane coupling agent may include epoxy silane, amino silane, ureido silane, mercapto silane, and alkyl silane. These may be used alone or in combination thereof.

In an implementation, the coupling agent may be present in an amount of about 0.01 wt % to about 5 wt %, based on the total weight of the epoxy resin composition. Within this range, a cured product of the composition can have increased strength. In an implementation, the coupling agent may be present in an amount of about 0.05 wt % to about 3 wt % in the epoxy resin composition.

Release Agent

The release agent may include, e.g., paraffin wax, ester wax, higher fatty acid, metallic salts of higher fatty acid, natural fatty acid, or metallic salts of natural fatty acid.

In an implementation, the release agent may be present in an amount of, e.g., about 0.01 wt % to about 1 wt %, in the epoxy resin composition.

In an implementation, the epoxy resin composition may further include, e.g., an antioxidant such as tetrakis[methylene-3-(3,5-di-tertbutyl-4-hydroxyphenyl)propionate]methane; or a flame retardant such as aluminum hydroxide, without altering the effects of the composition, as desired.

The epoxy resin composition may be produced into a film for encapsulation of semiconductor devices. The film for encapsulation of semiconductor devices may be fabricated through a process in which the epoxy resin composition is dissolved in an organic solvent and then applied in the form of a varnish to a base film, followed by heating, aging, and drying to remove volatile components from the varnish, thereby forming a composition layer. In the process of obtaining the varnish, an organic solvent may be used to facilitate acquisition of a blend of several components. The organic solvent may include, e.g., ketones, such as acetone, methyl ethyl ketone, or cyclohexanone, acetic acid esters, such as ethyl acetate, butyl acetate, cellosolve acetate, or propylene glycol monomethyl ether acetate, or aromatic hydrocarbon-containing solvents, such as toluene or xylene. These may be used alone or in combination thereof. The base film may include, e.g., polyester, polyimide, polyamide, polyether sulfone, polyphenylene sulfide, polyether ketone, polyether ether ketone, polyacetyl cellulose, polyetheramide, polyethylene naphthalate, polypropylene, or polycarbonate. In an implementation, a peelable release film may be used as the base film. Examples of the peelable release film may include polyolefins, such as polyethylene, polyvinyl chloride, or polypropylene, polyesters, such as polyethylene terephthalate, or release paper. The varnish may be applied to the base film by a suitable coating method, e.g., roll coating, gravure coating, microgravure coating, bar coating, or knife coating.

Another embodiment may provide a film for encapsulation of semiconductor devices, in which the epoxy resin composition in a semi-cured state is coated on a base film (e.g., a release-treated base film) or a release film.

Use of the epoxy resin composition in the form of a film may be advantageous in a semiconductor device packaging process in which a semiconductor device is packaged without being diced into individual chips (e.g., a panel level packaging (PLP) process) in that encapsulation of the semiconductor device is achieved by laminating the film onto the semiconductor device, e.g., onto a panel of undiced chips, followed by complete curing, whereby the semiconductor device may be encapsulated over a wider area in a simpler manner. The release-treated base film or the release film may be removed immediately after the lamination process, during the curing process, or after the curing process.

A thickness of the base film or the release film may be varied in consideration of semiconductor device packaging conditions and the like. In an implementation, the base film or the release film may have a thickness of about 10 to about 90 μm, e.g., about 25 μm to about 75 μm.

The film for encapsulation of semiconductor devices may be fabricated by a suitable method. In an implementation, the film for encapsulation of semiconductor devices may be fabricated by coating a coating solution containing the epoxy resin composition onto a base film (e.g., a release-treated base film) or a release film, followed by drying and semi-curing. In an implementation, drying may be performed at a temperature of about 70° C. to 90° C. for about 1 to 15 minutes, and semi-curing may be performed at a temperature of about 100° C. to 150° C. for about 1 to 10 minutes. The coating solution may be prepared by dissolving or dispersing the epoxy resin composition in a suitable solvent, e.g. propylene glycol methyl ether acetate (PGMEA), 2-butanone, methyl ethyl ketone (MEK), acetone, toluene, dimethylformamide (DMF), methyl cellosolve (MCS), tetrahydrofuran (THF), N-methylpyrrolidone (NMP), or propylene glycol methyl ether (PGME). Coating the epoxy resin composition may be performed by a suitable coating method, e.g., screen printing, knife coating, roll coating, spray coating, gravure coating, curtain coating, comma coating, or lip coating.

Another embodiment may provide a semiconductor device encapsulated using the film for encapsulation of semiconductor elements as set forth above. Encapsulation of the semiconductor device may be performed by compression molding, lamination, or a combination thereof.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

Details of components used in Examples and Comparative Examples were as follows:

(A) Liquid epoxy resin

(a1) KDS-8128 (Kukdo Chemical, Korea)

(a2) EP-4080E (Adeka Corp. Japan)

(a3) RE 304S (Nippon Kayaku Co., Ltd., Japan)

(B) Solid epoxy resin

(b1) NC-3000 (Nippon Kayaku Co., Ltd., Japan)

(b2) XD-1000H (Nippon Kayaku Co., Ltd., Japan)

(C) Curing agent

(c1) HF-3M (Meiwa Corp. Japan)

(c2) Melamine (Sigma Aldrich Corp., U.S.)

(c3) 4,4′-diaminodiphenylmethane (Sigma Aldrich Corp. U.S.)

(D) Binder resin: An Epoxy-modified acrylic copolymer (KG-8070, Negami Chemical, Japan)

(E) Spherical gadolinium oxide (D₅₀: 2.9 μm, sieving size: 10 μm)

(F) Spherical boron carbide (D₅₀: 4.6 μm, sieving size: 20 μm)

(G) Spherical silica (D₅₀: 0.58 μm, sieving size: 5 μm)

(H) Curing accelerator:

(h1) TPP-k, (Hokko Chemical, Japan)

(h2) 2-methylimidazole (Sigma Aldrich Corp., U.S.)

(h3) 4-pyrrolidinopyridine (Sigma Aldrich Corp., U.S.)

(I) Coupling agent: A-187, (Momentive Performance Materials Inc., U.S.)

### Examples 1 to 18 and Comparative Examples 1 to 4

An epoxy resin composition for semiconductor device encapsulation films prepared by mixing components listed in Table 1 or Table 2 was mixed with an organic solvent (a mixture of methyl ethyl ketone and propylene glycol methyl ether in a volume ratio of 2:1), thereby preparing a varnish (solid content: 70%), which, in turn, was coated onto a release film (RPK-201, thickness: 38 μm, Toray Advanced Materials Inc.) to a thickness of 120 μm, followed by drying in a convection oven at 80° C. for 7 minutes and at 125° C. for 3 minutes, thereby fabricating a film for encapsulation of semiconductor devices in a semi-cured state (B-stage), the film having a residual solvent content of 0.5 wt % or less.

TABLE 1
(Unit: wt %)

| | | Example | | | | | | | | | | |
|---|---|---|---|---|---|---|---|---|---|---|---|---|
| | | 1 | 2 | 3 | 4 | 5 | 6 | 7 | 8 | 9 | 10 | 11 |
| (A) | (a1) | 7.8 | — | 7.0 | — | 11.9 | — | 10.7 | — | 7.1 | — | — |
| | (a2) | — | 7.8 | | 7.0 | | 11.9 | | 10.7 | — | 7.1 | — |
| | (a3) | — | — | — | — | — | — | — | — | — | — | 5.5 |
| (B) | (b1) | — | — | — | — | — | — | — | — | — | — | 4.1 |
| | (b2) | 5.9 | 5.9 | 5.3 | 5.3 | — | — | — | — | 5.3 | 5.3 | — |
| (C) | (c1) | — | — | — | — | — | — | — | — | — | — | 5.4 |
| | (c2) | 1.3 | 1.3 | — | — | 1.1 | 1.1 | — | — | — | — | — |
| | (c3) | — | — | 2.7 | 2.7 | — | — | 2.3 | 2.3 | — | — | — |
| (D) | | 4.0 | 4.0 | 4.0 | 4.0 | 6.0 | 6.0 | 6.0 | 6.0 | 6.0 | 6.0 | 4.0 |
| (E) | | 40 | 40 | 40 | 40 | 40 | 40 | 40 | 40 | 40 | 40 | 40 |
| (F) | | 40 | 40 | 40 | 40 | 40 | 40 | 40 | 40 | 40 | 40 | 40 |
| (G) | | — | — | — | — | — | — | — | — | — | — | — |
| (H) | (h1) | — | — | — | — | — | — | — | — | — | — | 0.03 |
| | (h2) | — | — | 0.03 | 0.03 | — | — | 0.03 | 0.03 | 0.63 | 0.63 | — |
| | (h3) | 0.03 | 0.03 | — | — | 0.03 | 0.03 | — | — | — | — | — |

| | | | | | | | | | | | |
|---|---|---|---|---|---|---|---|---|---|---|---|
| (I) | 0.97 | 0.97 | 0.97 | 0.97 | 0.97 | 0.97 | 0.97 | 0.97 | 0.97 | 0.97 | 0.97 |

TABLE 2
(Unit: wt %)

| | | Example | | | | | | | Comparative Example | | | |
|---|---|---|---|---|---|---|---|---|---|---|---|---|
| | | 12 | 13 | 14 | 15 | 16 | 17 | 18 | 1 | 2 | 3 | 4 |
| (A) | (a1) | — | — | — | — | — | — | — | — | — | — | — |
| | (a2) | — | 5.5 | 5.5 | — | — | 7.8 | 7.8 | — | 9.1 | 4.2 | — |
| | (a3) | 5.5 | — | — | 7.8 | 7.0 | — | — | 5.5 | — | — | — |
| (B) | (b1) | — | 4.1 | — | 5.9 | 5.3 | — | — | 4.1 | — | — | — |
| | (b2) | 4.1 | — | 4.1 | — | — | 5.9 | 5.9 | — | 6.9 | 3.1 | 13.7 |
| (C) | (c1) | 5.4 | 5.4 | 5.4 | — | — | — | — | 5.4 | — | — | — |
| | (c2) | — | — | — | 1.3 | — | 1.3 | 1.3 | — | 1.5 | 0.7 | 1.3 |
| | (c3) | — | — | — | — | 2.7 | — | — | — | — | — | — |
| (D) | | 4.0 | 4.0 | 4.0 | 4.0 | 4.0 | 4.0 | 4.0 | 4.0 | 1.5 | 11 | 4.0 |
| (E) | | 40 | 40 | 40 | 40 | 40 | 80 | — | — | 40 | 40 | 40 |
| (F) | | 40 | 40 | 40 | 40 | 40 | | 80 | — | 40 | 40 | 40 |
| (G) | | — | — | — | — | — | — | — | 80 | — | — | — |
| (H) | (h1) | 0.03 | 0.03 | 0.03 | — | — | — | — | 0.03 | — | — | — |
| | (h2) | — | — | — | — | 0.03 | — | — | — | — | — | — |
| | (h3) | — | — | — | 0.03 | — | 0.03 | 0.03 | — | 0.03 | 0.03 | 0.03 |

| | | | | | | | | | | | |
|---|---|---|---|---|---|---|---|---|---|---|---|
| (I) | 0.97 | 0.97 | 0.97 | 0.97 | 0.97 | 0.97 | 0.97 | 0.97 | 0.97 | 0.97 | 0.97 |

Each of the films for encapsulation of semiconductor devices fabricated in the Examples and Comparative Examples was evaluated as to physical properties shown in Tables 3 and 4.

(1) Film formability (wettability): Immediately after coating and semi-curing operations, the presence or absence of defects in the form of pinholes, craters, and blisters was determined with the naked eye.

(2) Neutron shielding rate (unit: %): After preparing three specimens of each of the films for encapsulation of semiconductor devices fabricated in the Examples and Comparative Examples, two of the specimens were placed one above another with respective resin layers thereof abutting one another and then attached to one another using a laminator, followed by removal of the release films thereof. Then, the other specimen was placed on the resulting film stack with a resin layer thereof abutting the film stack and then attached to the film stack using the laminator, followed by removal of the release film thereof, thereby obtaining a film stack having an overall thickness of 360 μm. Then, the film stack was cured at 180° C. for 90 minutes, thereby obtaining a final cured product sample. A neutron shielding rate of the obtained sample was determined by neutron radioactivation analysis that measured and analyzed the radiation dose of radioactive isotopes generated by neutron reactions, under the following conditions:
Neutron source: 5MW research reactor
Energy level of incident neutrons: 0 MeV to 10 MeV (neutrons having an energy level of 1 eV: neutrons having an energy level of 10 MeV or more=4:1)
Neutron fluence (neutrons/cm²sec): 7.8×10⁸

(3) Adhesion

\textcircled{1} Lowest melt viscosity (unit: Pa·s): Melt viscosity of each of the semi-cured films for encapsulation of semiconductor devices fabricated in the Examples and Comparative Examples was measured under conditions of a heating rate of 10° C./min, a strain of 5%, a frequency of 1 rad, and a temperature range of 30° C. to 200° C. using a parallel plate and an aluminum disposable plate (diameter: 8 mm) (ARES G2, TA Instruments). The lowest melt viscosity in the temperature range of 30° C. to 200° C. was recorded.

\textcircled{2} Peel strength (unit: gf/cm): Each of the semi-cured films for encapsulation of semiconductor devices fabricated in the Examples and Comparative Examples was placed on a Cu-clad laminate with the resin layer thereof abutting the laminate and then attached to the laminate under conditions of 110° C. and 1 m/min using a laminator, followed by removal of the release film thereof. Then, the resultant was cured at 180° C. for 90 minutes, thereby obtaining a cured product sample. Peel strength was measured on the cured product sample at a peeling angle of 90° using a universal testing machine (UTM).

(4) Thermal Reliability

\textcircled{1} Thermogravimetric analysis (TGA, unit: %): Each of the semi-cured films for encapsulation of semiconductor devices fabricated in the Examples and Comparative Example was subjected to primary curing at 110° C. for 30 minutes, followed by removal of the release film thereof. Then, secondary curing was performed at 180° C. for 60 minutes, thereby obtaining a cured product sample. The obtained cured product sample was heated from 25° C. to 800° C. at a heating rate of 10 K/min in a nitrogen atmosphere, and a weight loss (%) occurring at 300° C. was taken as data.

\textcircled{2} Solder immersion (measurement of maximum heat-resistance temperature): Each of the semi-cured films for encapsulation of semiconductor devices fabricated in the Examples and Comparative Examples was placed on a Cu-clad laminate with the resin layer thereof abutting the laminate and then attached to the laminate using a laminator under conditions of 110° C. and 1 m/min, followed by removal of the release film thereof. Then, the resultant was cured at 180° C. for 90 minutes, thereby obtaining a cured product sample. Then, the cured product sample was immersed in a solder pot (initial temperature: 220° C.), which, in turn, was heated at a heating rate of 10° C./min, followed by measurement of the highest temperature that the sample could withstand without formation of voids therein or delamination from the Cu-clad laminate. The measured highest temperature was defined as “maximum heat-resistance temperature”.

(5) Dielectric breakdown voltage (unit: kV/mm): Each of the semi-cured films for encapsulation of semiconductor devices fabricated in the Examples and Comparative Example was subjected to primary curing at 110° C. for 30 minutes, followed by removal of the release film thereof. Then, secondary curing was performed at 180° C. for 60 minutes, thereby obtaining a cured product sample. Dielectric breakdown voltage was measured by applying AC voltage to the obtained cured product sample at room temperature in accordance with ASTM D149.

TABLE 3

| | Example | | | | | | | | | | |
|---|---|---|---|---|---|---|---|---|---|---|---|
| | 1 | 2 | 3 | 4 | 5 | 6 | 7 | 8 | 9 | 10 | 11 |
| Wettability | Good | Good | Good | Good | Good | Good | Good | Good | Good | Good | Good |
| Neutron shielding | 67.9 | 70.0 | 67.0 | 69.7 | 73.1 | 74.9 | 71.7 | 72.9 | 67.6 | 69.0 | 60.9 |
| rate | | | | | | | | | | | |
| Lowest melt | 19,000 | 18,000 | 22,000 | 20,000 | 16,000 | 15,000 | 17,000 | 16,000 | 21,000 | 19,000 | 24,000 |
| viscosity | | | | | | | | | | | |
| Peel strength | 670 | 550 | 650 | 520 | 450 | 370 | 490 | 420 | 540 | 520 | 450 |
| TGA | 0.6 | 0.6 | 0.5 | 0.6 | 2.8 | 3.0 | 1.5 | 1.6 | 1.9 | 2.5 | 0.8 |
| Solder immersion | 320 | 330 | 320 | 300 | 270 | 250 | 280 | 260 | 270 | 260 | 320 |
| Dielectric | 12 | 12 | 11 | 10 | 13 | 12 | 11 | 11 | 12 | 12 | 12 |
| breakdown | | | | | | | | | | | |
| voltage | | | | | | | | | | | |

TABLE 4

| | Example | | | | | | | Comparative Example | | | |
|---|---|---|---|---|---|---|---|---|---|---|---|
| | 12 | 13 | 14 | 15 | 16 | 17 | 18 | 1 | 2 | 3 | 4 |
| Wettability | Good | Good | Good | Good | Good | Good | Good | Good | Defects | Good | Good |
| | | | | | | | | | occurred | | |
| Neutron shielding | 61.5 | 61.9 | 62.2 | 63.0 | 62.5 | 56.1 | 53.1 | 1.2 | — | — | 59.9 |
| rate | | | | | | | | | | | |
| Lowest melt | 18,000 | 19,000 | 22,000 | 18,000 | 19,000 | 22,000 | 26,000 | 31,000 | — | 87,000 | 54,000 |
| viscosity | | | | | | | | | | | |
| Peel strength | 410 | 500 | 520 | 530 | 540 | 470 | 440 | 330 | — | Impossible | 220 |
| | | | | | | | | | | to attach | |
| TGA | 0.6 | 0.6 | 0.7 | 0.8 | 0.7 | 0.7 | 0.7 | 0.7 | — | 3.6 | 3.1 |
| Solder immersion | 320 | 310 | 310 | 300 | 310 | 310 | 300 | 320 | — | — | 240 |
| Dielectric | 11 | 12 | 11 | 10 | 10 | 10 | 9 | 12 | — | 10 | 9 |
| breakdown | | | | | | | | | | | |
| voltage | | | | | | | | | | | |

From Tables 3 and 4, it may be seen that the films for encapsulation of semiconductor devices of Examples 1 to 18, fabricated using the composition according to the embodiments, had a peel strength of 350 gf/cm or more and a maximum heat-resistance temperature of 250° C. or higher, and thus exhibited good adhesion and heat resistance while having high neutron shielding capability. Conversely, the film of Comparative Example 1, fabricated using a composition free from an oxide, nitride, carbide, or hydroxide of gadolinium, boron, samarium, cadmium, or europium, had poor neutron shielding capability. In addition, the film of Comparative Example 2, fabricated using the composition in which the amount of the binder resin were less than the amounts of the Examples, had defects due to poor wettability of the composition and was not suitable for use as a film for encapsulation of semiconductor devices. Further, the film of Comparative Example 3, fabricated using the composition in which the amount of the binder resin exceeded the amounts of the Examples, and the film of Comparative Example 4, fabricated using a solid epoxy resin instead of a liquid epoxy resin, had poor adhesion.

By way of summation and review, neutrons are small in size and have no charge. Thus, neutrons readily penetrate the fuselage of an aircraft, which is formed of aluminum or carbon composites, into the aircraft and then collide with atomic nuclei of silicon (Si) and silicon dioxide (SiO₂) in semiconductor devices in transit, potentially causing total ionizing dose (TID) defects.

Further, with micronization or miniaturization of semiconductor devices due to advancements of semiconductor manufacturing technology, the influence of neutron-induced TID defects on semiconductor devices is growing. Neutron-induced TID defects of semiconductor devices during air transportation may be reduced.

One or more embodiments may provide an epoxy resin composition for semiconductor device encapsulation films, which can provide neutron shielding.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for semiconductor device encapsulation films, the epoxy resin composition comprising:
a liquid epoxy resin;
a curing agent;
about 2 wt % to about 10 wt % of a binder resin; and
about 50 wt % or more of an oxide, a nitride, a carbide, or a hydroxide of gadolinium, boron, samarium, cadmium, or europium, all wt % being based on a total weight of the epoxy resin composition.

2. The epoxy resin composition as claimed in claim 1, wherein the liquid epoxy resin includes a bisphenol A epoxy resin, a hydrogenated bisphenol A epoxy resin, or a combination thereof.

3. The epoxy resin composition as claimed in claim 1, wherein the binder resin includes an epoxy-modified (meth)acrylic copolymer.

4. The epoxy resin composition as claimed in claim 1, wherein the oxide, nitride, carbide, or hydroxide of gadolinium, boron, samarium, cadmium, or europium has an average particle diameter (D₅₀) of about 0.1 μm to about 50 μm.

5. The epoxy resin composition as claimed in claim 1, wherein the oxide, nitride, carbide, or hydroxide of gadolinium, boron, samarium, cadmium, or europium is present in an amount of about 50 wt % to about 90 wt %, based on the total weight of the epoxy resin composition.

6. The epoxy resin composition as claimed in claim 1, wherein the epoxy resin composition includes at least two of an oxide, a nitride, a carbide, or a hydroxide of gadolinium, boron, samarium, cadmium, or europium.

7. The epoxy resin composition as claimed in claim 6, wherein one oxide, nitride, carbide, or hydroxide of gadolinium, boron, samarium, cadmium, or europium of the at least two oxides, nitrides, carbides, or hydroxides of gadolinium, boron, samarium, cadmium, or europium has an average particle diameter (D₅₀) that is different from that of the other oxide, nitride, carbide, or hydroxide of gadolinium, boron, samarium, cadmium, or europium of the at least two oxides, nitrides, carbides, or hydroxides of gadolinium, boron, samarium, cadmium, or europium.

8. The epoxy resin composition as claimed in claim 1, wherein the epoxy resin composition includes:
about 0.5 wt % to about 25 wt % of the liquid epoxy resin;
about 0.1 wt % to about 15 wt % of the curing agent;
about 2 wt % to about 10 wt % of the binder resin; and
about 50 wt % to about 90 wt % of the oxide, nitride, carbide, or hydroxide of gadolinium, boron, samarium, cadmium, or europium, all wt % being based on a total weight of the epoxy resin composition.

9. A film for encapsulation of semiconductor devices, the film comprising:
a base film or a release film; and
an epoxy resin composition coated on the base film or the release film, the epoxy resin composition being in a semi-cured state,
wherein the epoxy resin composition includes the epoxy resin composition for semiconductor device encapsulation films as claimed in claim 1.

10. The film as claimed in claim 9, wherein the liquid epoxy resin includes a bisphenol A epoxy resin, a hydrogenated bisphenol A epoxy resin, or a combination thereof.

11. The film as claimed in claim 9, wherein the binder resin includes an epoxy-modified (meth)acrylic copolymer.

12. The film as claimed in claim 9, wherein the oxide, nitride, carbide, or hydroxide of gadolinium, boron, samarium, cadmium, or europium has an average particle diameter (D₅₀) of about 0.1 μm to about 50 μm.

13. The film as claimed in claim 9, wherein the oxide, nitride, carbide, or hydroxide of gadolinium, boron, samarium, cadmium, or europium is present in an amount of about 50 wt % to about 90 wt %, based on the total weight of the epoxy resin composition.

14. The film as claimed in claim 9, wherein the epoxy resin composition includes at least two of an oxide, a nitride, a carbide, or a hydroxide of gadolinium, boron, samarium, cadmium, or europium.

15. The film as claimed in claim 14, wherein one oxide, nitride, carbide, or hydroxide of gadolinium, boron, samarium, cadmium, or europium of the at least two oxides, nitrides, carbides, or hydroxides of gadolinium, boron, samarium, cadmium, or europium has an average particle diameter (D₅₀) that is different from that of the other oxide, nitride, carbide, or hydroxide of gadolinium, boron, samarium, cadmium, or europium of the at least two oxides, nitrides, carbides, or hydroxides of gadolinium, boron, samarium, cadmium, or europium.

16. The film as claimed in claim 9, wherein the epoxy resin composition includes:
about 0.5 wt % to about 25 wt % of the liquid epoxy resin;
about 0.1 wt % to about 15 wt % of the curing agent;
about 2 wt % to about 10 wt % of the binder resin; and
about 50 wt % to about 90 wt % of the oxide, nitride, carbide, or hydroxide of gadolinium, boron, samarium, cadmium, or europium, all wt % being based on a total weight of the epoxy resin composition.

17. A semiconductor device encapsulated using the film for encapsulation of semiconductor devices as claimed in claim 9.
